(19) United States
(12) Patent Application Publication
(10) Pub. No.: US 2024/0422945 A1
(43) Pub. Date: Dec. 19, 2024

(54) EMBEDDED THERMAL INTERFACE FOR CAGE MOUNTED ELECTRONIC DEVICES

(71) Applicant: AirBorn, Inc., Georgetown, TX (US)

(72) Inventors: Andrew Tarnow, Windsor, SC (US); Donald Lucas, Windham, NH (US); Carl Cody, Erie, PA (US); Tristan Kuhns, Lake City, PA (US); Nathan Groover, Erie, PA (US); Brian Mroczkowski, Erie, PA (US); Gary VanMeter, Lake City, PA (US); William Cermak, Fairview, PA (US); Scott Poole, Girard, PA (US)

(21) Appl. No.: 18/742,580

(22) Filed: Jun. 13, 2024

Related U.S. Application Data
(60) Provisional application No. 63/472,715, filed on Jun. 13, 2023.

(51) Int. Cl. H05K 7/20; H05K 7/14

(52) U.S. Cl. CPC H05K 7/2039; H05K 7/1424

(57) ABSTRACT

Thermal interface system, and method thereof, are configured to constrain or limit an amount of compression applied to a thermal interface during insertion of an electronic device into a cage, rack, chassis, or other mounting assembly. The thermal interface system and method provide a thermal interface that is embedded within a pocket or cavity formed either on a surface of the device, a surface of the mounting assembly, or both. The thermal interface may be made of any suitable thermally conductive interface material that is resilient or has elastic properties. The pocket or cavity provides a seating for the thermal interface and operates to limit the compression or clamping force directed through the thermal interface. Such an arrangement helps prevent the full compression or clamping force used to secure the electronic device from being applied to the thermal interface.

### CROSS-REFERENCE TO RELATED APPLICATIONS

This application for patent claims the benefit of priority to and incorporates herein by reference U.S. Provisional Application No. 63/472,715, entitled “Embedded Thermal Interface for Cage Mounted Electronic Devices,” filed Jun. 13, 2023.

### TECHNICAL FIELD

The present disclosure relates to improved thermal interfaces for heat dissipation in electronic devices of the type that are mounted in cages, racks, and other mounting chassis.

### BACKGROUND

Modern electronic devices often generate a significant amount of heat during operation. The excessive heat produced by these devices needs to be dissipated efficiently in order for the devices to continue operating according to their specifications. However, heat dissipation can be an issue for electronic devices with very small form factors (i.e., size, shape, configuration), such as “card” or “blade” shaped devices. Due to their reduced surface areas, these devices often have difficulty dissipating large amounts of heat quickly.

Several techniques exist for dissipating heat quickly from small form factor devices. One technique is to conduct the heat from the small device into another device with a larger heat dissipating surface that can dissipate a larger amount of heat (i.e., a heatsink). The second device can in turn more effectively dissipate the heat into the ambient environment. A thermal interface can be used to facilitate the transfer of heat from the first device to the device with the larger heat dissipating surface. However, although a thermal interface can facilitate heat transfer between two heat conductive surfaces, such thermal interfaces have a much higher thermal resistance path compared to the same geometry formed as a unitary piece, with no thermal interface.

Another consideration is the temperature rise in the thermal interface. The temperature rise in a thermal interface material for a given rate of heat transfer through conduction depends on the material's specific thermal resistivity and the cross-sectional area of the material conducting the heat transfer. The temperature rise for heat transfer across an air gap without direct conduction is typically a combination of radiative transfer and, if a fluid medium (e.g., air) is present in the interface, convective transfer. Radiative and convective heat transfer tend to be less effective, requiring a higher temperature difference for a similar rate of heat flow compared to conductive heat transfer in materials that perform well as thermal conductors.

Further, when two rigid materials are in contact with each other, the physical contact between the materials is primarily between high spots on each material that align in a way such that they are touching. The cross-sectional area available for conductive heat transfer is thus limited to the contact area between these high spots on the materials. Heat transfer through the remainder of the interface, without such contacts, must rely on radiative transfer and, if a fluid medium like air is present, convective transfer. Conductive heat transfer, however, is significantly more effective over a given area compared to convective or radiative heat transfer. Therefore, increasing the contact area between the two materials, and thereby reducing the overall thermal impedance, can have a significant improvement in the heat transfer through the interface.

Several approaches exist for improving thermal transfer by reducing the thermal impedance in a thermal interface. One approach is to use liquids, such as greases, greases with suspended solid particles, pre-cured gels, and pastes, as the thermal interface. These materials typically are one-time-use products where, after an application, they need to be removed and re-applied to achieve the coverage desired. They work well in situations where there can be a controlled application with each mating of a thermal interface.

Another approach is to use compliant phase change materials as the thermal interface. These materials are applied as a solid, and with use, turn into a liquid at high temperature and flow to fill in voids in the surfaces. Like the liquids approach, these materials typically require re-application every time a thermal interface connection is made. They often also require re-tightening of the hardware, applying mechanical pressure to the thermal interface after the initial liquid transitions due to volume loss of material as it flows into uneven surfaces and out from inside the thermal interface, both initially after the first phase change, and over time.

Yet another approach is to use mechanically compliant materials as the thermal interface. These materials are typically in the form of pads with pre-defined geometries and are designed to compress sufficiently to fill in uneven features in the target surfaces. Depending on the thickness of the pads, these features may be on the micro scale only, or on both the micro and macro scale.

While the heat transfer effectiveness through thermal pads is much better than through an air gap, it is typically not as good as the materials that are structural, such as copper or aluminum. Because of this, the thermal pad thickness is typically optimized to be only as thick as required to fill in the gaps in a given application. But even the thinnest of thermal pads and/or minimally elastic thermal pads require a significant force to compress the material into the mating surfaces of the thermal interface. These thermal pads often still require a reasonably smooth finish on the interface materials, and significant pressure applied to the interface.

Thicker thermal pads have elastic properties under compression. If compressed in a working range, often targeted at 20% compression, and possibly in the range of 5% to 70% compression, depending on the material type, these pads require lower pressure per percent deflection than a thinner pad, and may fill in both gaps from micro and macro features on the thermal interface.

Often these thicker pads are used in applications where there is a mechanical structure that constrains the percentage of compression into a target range, as over-compression can lead to non-elastic compression or other damage. As long as the pads are used in their elastic range, they are reusable without any type of rework or repair, unlike liquids or phase change materials.

In all of the above approaches, if the mechanical force applied by the fasteners securing the device is countered by the material in the thermal interface, then a pressure is developed on the thermal interface material that counters the fasteners force. As a result, any bolt stretch or other elastic force in the hardware clamping the device needs to be supported by the thermal interface material. If the thermal interface material's geometric or elastic properties change, such as a phase change material flowing, a grease or gel flowing, or an elastic undergoing inelastic compression, then there will be a reduction in the elastic force on the hardware securing the device. This leads to a reduction in pressure on the thermal interface, which may result in a reduction in thermal performance, and also a reduction in force on the hardware securing the device. Such a reduction in force could lead to the device no longer being held in place while in service and/or hardware loosening that would further reduce the mechanical support provided to the device.

The reduction in pressure on the thermal interface is particularly problematic for applications where an electronic device is slid into a mounting assembly prior to mechanically clamping the device. For example, card or blade shaped devices are often used as modules that are slid into a “card cage,” a rack, a chassis, or similar mounting assembly. The action of sliding the module into the card cage can disturb and even remove some of the thermal interface material that was applied to the surface(s) of the module, thereby compromising the efficacy of the thermal interface.

The potential for disturbing or partially removing the thermal interface material during installation/reinstallation of a card or blade shaped device also limits the ability of manufacturers to pre-apply thermal interface materials to the device. With the material pre-applied and material's geometries prescribed, the electronic device essentially becomes a single-use device, as removal of the device from the cage, rack, chassis, or other mounting assembly requires sending the device back for rework and/or reapplication of the thermal interface material prior to re-installation of the device.

Accordingly, while many advances have been made in the field of heat dissipation for electronic devices, it will be readily appreciated that improvements are continually needed.

### SUMMARY

Embodiments of the present disclosure relate to improvements in heat dissipation for electronic devices, particularly in card and blade shaped electronic devices. The embodiments effect a thermal interface system, and method thereof, that can constrain or limit the amount of compression applied to a thermal interface during insertion of the electronic device into a cage, rack, chassis, or other mounting assembly. In some embodiments, the thermal interface system and method provide a thermal interface that is embedded within a pocket or cavity formed either on a surface of the device, a surface of the mounting assembly, or both. The thermal interface may be made of any suitable thermally conductive interface material that is resilient or has elastic properties. The pocket or cavity provides a seating for the thermal interface and operates to limit the compression or clamping force directed through the thermal interface. Such an arrangement thus helps prevent the full compression or clamping force used to secure the electronic device in the mounting assembly from being applied to the thermal interface.

In general, in one aspect, embodiments of the present disclosure relate to an embedded thermal interface system. The system comprises, among other things, a thermally conductive structure, and at least one thermal interface pocket formed in a surface of the thermally conductive structure, the at least one thermal interface pocket having a predefined pocket depth. The system further comprises a resilient thermal interface seated within the at least one thermal interface pocket, the resilient thermal interface having a predefined thermal interface thickness. The thermal interface thickness of the resilient thermal interface is greater than the pocket depth of the at least one thermal interface pocket, such that the resilient thermal interface protrudes from the at least one thermal interface pocket when the resilient thermal interface is seated within the at least one thermal interface pocket.

In general, in another aspect, embodiments of the present disclosure relate to a method of assembling an embedded thermal interface system. The method comprises providing a thermally conductive structure and forming at least one thermal interface pocket in a surface of the thermally conductive structure, the at least one thermal interface pocket having a predefined pocket depth. The method further comprises seating a resilient thermal interface within the at least one thermal interface pocket, the resilient thermal interface having a predefined thermal interface thickness. The thermal interface thickness of the resilient thermal interface is greater than the pocket depth of the at least one thermal interface pocket, such that the resilient thermal interface protrudes from the at least one thermal interface pocket when the resilient thermal interface is seated within the at least one thermal interface pocket.

In general, in yet another aspect, embodiments of the present disclosure relate to an electronic assembly. The electronic assembly comprises, among other things, a card cage, at least one electronic device mounted in the card cage, and a thermal interface system disposed in the card cage. The thermal interface system comprises a thermally conductive structure, and at least one thermal interface pocket formed in a surface of the thermally conductive structure, the at least one thermal interface pocket having a predefined pocket depth. The thermal interface system further comprises a resilient thermal interface seated within the at least one thermal interface pocket, the resilient thermal interface having a predefined thermal interface thickness. The thermal interface thickness of the resilient thermal interface is greater than the pocket depth of the at least one thermal interface pocket, such that the resilient thermal interface protrudes from the at least one thermal interface pocket when the resilient thermal interface is seated within the at least one thermal interface pocket.

In accordance with any one or more of the foregoing embodiments, when compressive force is applied to the resilient thermal interface, the at least one thermal interface pocket prevents the compressive force from being fully applied to the resilient thermal interface.

In accordance with any one or more of the foregoing embodiments, the thermally conductive structure is on or part of a housing of an electronic device, and in some embodiments, the housing of the electronic device has mounting guides projecting therefrom and the at least one thermal interface pocket is formed in a surface of at least one of the mounting guides, or the housing of the electronic device has a mating face thereon and the at least one thermal interface pocket is formed in a surface of the mating face.

In accordance with any one or more of the foregoing embodiments, the thermally conductive structure is on or part of a mounting mechanism of a mounting assembly, and in some embodiments, the mounting mechanism of the mounting assembly is a guide rail and the thermal interface pocket is formed in a surface of the guide rail.

### BRIEF DESCRIPTION OF THE DRAWINGS

FIGS. 1A, 1B, and 1C are top and cross-sectional views showing an exemplary thermal interface system according to embodiments of the present disclosure.

FIGS. 2A, 2B, 2C, 2D, and 2E are top, side, and cross-sectional views showing an exemplary thermal interface system used in an exemplary card rack according to embodiments of the present disclosure.

FIG. 3 is a perspective view showing an exemplary card cage according to embodiments of the present disclosure.

FIGS. 4A and 4B are top and cross-sectional views showing another exemplary thermal interface system according to embodiments of the present disclosure.

FIGS. 5A and 5B are side and cross-sectional views showing a thermal interface system attached to a heatsink according to embodiments of the present disclosure.

FIG. 6 is a flowchart representing an exemplary method that may be used to implement a thermal interface system according to embodiments of the present disclosure.

### DETAILED DESCRIPTION

As an initial matter, it will be appreciated that the development of an actual, real commercial application incorporating aspects of the disclosed embodiments will require many implementation specific decisions to achieve the developer's ultimate goal for the commercial embodiment. Such implementation specific decisions may include, and likely are not limited to, compliance with system related, business related, government related and other constraints, which may vary by specific implementation, location and from time to time. While a developer's efforts might be complex and time consuming in an absolute sense, such efforts would nevertheless be a routine undertaking for those of skill in this art having the benefit of this disclosure.

It should also be understood that the embodiments disclosed and taught herein are susceptible to numerous and various modifications and alternative forms. Thus, the use of a singular term, such as, but not limited to, “a” and the like, is not intended as limiting of the number of items. Similarly, any relational terms, such as, but not limited to, “top,” “bottom,” “left,” “right,” “upper,” “lower,” “down,” “up,” “side,” and the like, used in the written description are for clarity in specific reference to the drawings and are not intended to limit the scope of the invention.

As alluded to above, embodiments of the present disclosure provide a thermal interface system, and method thereof, for dissipating heat in electronic devices, particularly card or blade shaped electronic devices. The thermal interface system and method can constrain or limit how much compression is applied to a thermal interface when an electronic device is inserted into a cage, rack, chassis, or other mounting assembly. In some embodiments, the limiting of the compression can be achieved by providing a pocket or cavity either on a surface of the device, a surface of the mounting assembly, or both, and embedding the thermal interface within the pocket or cavity. The thermal interface may be any suitable thermally conductive interface material that is resilient or has elastic properties, or otherwise tries to regain its original shape and volume when compressed. The pocket or cavity operates to contain the thermal interface and also limits the amount of compression or clamping force that can be applied to the thermal interface. Embedding the thermal interface in this way thus helps protect the thermal interface, including from large amounts of compression or clamping force, such as the force exerted by mounting hardware to secure the electronic device in the mounting assembly.

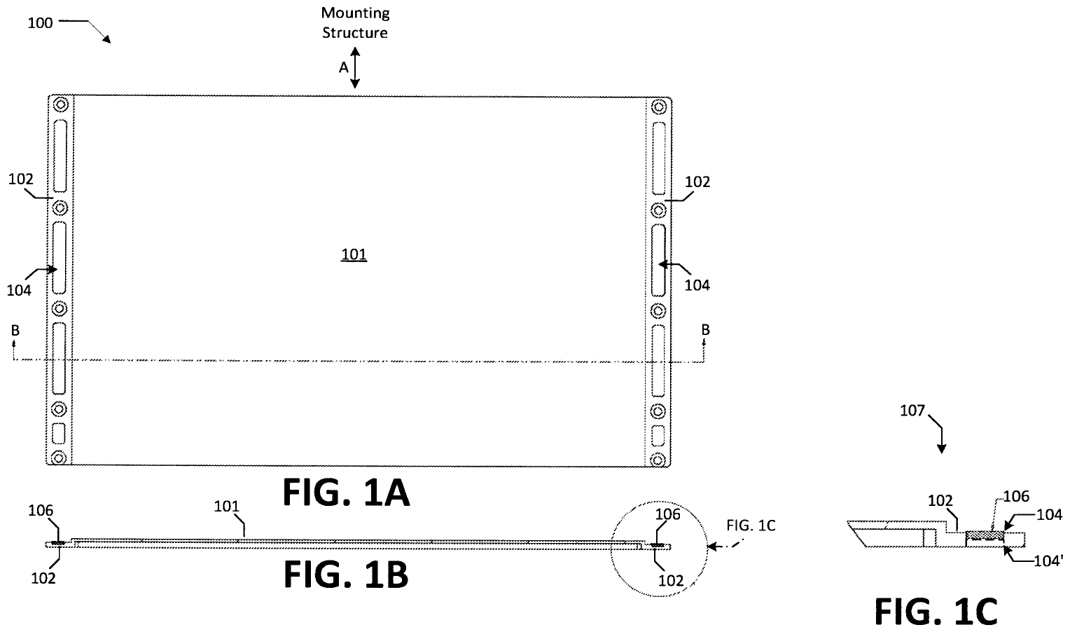

Referring now to FIGS. 1A, 1B, and 1C, top, front cross-sectional, and side cross-sectional views are shown for an exemplary electronic device 100 that employs an embedded thermal interface according to embodiments of the present disclosure. The electronic device 100 in this example is a card or blade type device having a generally planar rectangular shape that is often used for power converter modules and similar types of modules. It will be appreciated, however, that the embedded thermal interface embodiments described herein are not limited to card and blade type devices, and are equally applicable to numerous other form factors.

In the embodiment shown, the electronic device 100 has a main enclosure or housing 101 composed of a thermally conductive material, such as a metal or a metal alloy, and configured to house various electronic components (not expressly shown). The housing 101 has a generally planar rectangular mounting guide 102 that is likewise made of a thermally conductive material and resembles a ledge or step-down projecting from opposing sides of the main housing 101 in parallel to one another along the main housing 101. The mounting guides 102 preferably, but not necessarily, extend along the full length of the main housing 101 and are configured to allow the electronic device 100 to be mounted to a corresponding mounting mechanism of a cage, rack, chassis, or other mounting assembly. The mounting mechanism may be a bolt-on type mounting mechanism, a snap-on type mounting mechanism, or it may be a slide-in type mounting mechanism (e.g., slot, aperture, etc.) that allows the electronic device 100 to be slid into the mounting assembly in the direction indicated by double-headed arrow “A.”

A plurality of generally rectangular, elongate thermal interface cavities or pockets 104 are formed in a surface of the guides 102 roughly equal distance apart from one another. Each elongate pocket 104 has a generally uniform, predefined depth therein that may be provided by machining the guides 102, etching, or other metalworking techniques known to those having ordinary skill in the art. There are three elongate pockets 104 on each guide 102 in the embodiment shown, with other embodiments having fewer or more elongate pockets 104 as needed. It will be appreciated that other shapes known to those skilled in the art may be used for the thermal interface pockets 104, such as oval, triangular, trapezoidal, and the like.

As best seen in FIG. 1C, a generally rectangular, elongate thermal interface 106 is disposed within one or more, or each, of the thermal interface pockets 104. Each thermal interface 106 has a generally uniform, predefined thickness that is slightly greater than the pocket depth of each pocket 104, and therefore a portion of the thermal interface 106 protrudes from the pocket 104 when the thermal interface 106 is seated in the pocket 104. As discussed above, the thermal interface 106 may be made of any suitable thermally conductive interface material that is resilient or has elastic properties that cause the thermal interface 106 to try and return to its original shape and volume when compressed. Examples include silicone-based thermal interface materials, elastomer-based thermal interface materials, and the like. The side of the device 100 from which the thermal interface 106 protrudes is considered a mating face 107 and, where applicable, the device 100 mates to the mounting assembly via this mating face 107.

In general operation, when the device 100 is mounted in a mounting assembly, the mounting mechanism of the mounting assembly exerts a clamping force on the mounting guides 102 of the device 100 to secure the device 100 in the mounting assembly. When this happens, the portion of the thermal interface 106 protruding beyond each pocket 104 is compressed by the mounting mechanism. The compression ensures flush physical (and hence thermal) contact between each thermal interface 106, the mounting assembly, and the device 100 due to the resiliency of the thermal interface 106 resisting or pushing back against the compression. When the compression of the thermal interface 106 reaches the guides 102, however, the top surface of the guides 102 counter the clamping force exerted by the mounting mechanism on the thermal interface 106, thereby physically preventing the mounting mechanism from compressing the thermal interface 106 further into the pocket 104. As a result, there is no need to rely on the mechanical properties of the thermal interface 106 to withstand the clamping force, since the thermal interface 106 cannot be compressed further within the pocket 104.

As mentioned, the thermal interface 106 may be selected based on its elastic material properties and its thickness such that when the thermal interface 106 is embedded in the pocket 104, the thermal interface 106 can be compressed, yet still maintain some or all of its pre-installation elasticity. This elasticity or resiliency lets the thermal interface 106 push against both of the surfaces between which the thermal interface 106 is being compressed, thereby allowing it to maintain sufficient physical (and hence thermal) contact to provide a thermal bridge between the surfaces, independent of the clamping force applied by the hardware securing the connection structurally.

In an example embodiment, approximately 0.030 inch deep pockets 104 are machined into the mounting guides 102 of the device 100. The thermal interfaces 106 in this embodiment may have a thickness of approximately 0.040 inches, which allows for approximately 25% compression of the thermal interfaces 106 when the device 100 is secured to a mounting assembly. In some embodiments, the thermal interfaces 106 may have a thickness ranging from approximately 0.005 inches to 0.500 inches before compression, depending on material selection, desired performance, and other engineering design considerations, leading to percent compressions ranging from approximately 5% to 80%. The specific amount of pressure experienced by the thermal interfaces 106 depends on the percent compression, the material thickness, and the material properties of the thermal interfaces 106, and is independent of the compression or clamping force that secures the device 100 mechanically to the mounting assembly.

In the example embodiment of FIGS. 1A, 1B, and 1C, the pockets 104 are formed (e.g., machined) on one side of the guides 102. In other example embodiments, the pockets 104 may be formed on both sides of the guides 102, as indicated by the dashed lines 104′ in FIG. 1C, such that the thermal interfaces 106 may be embedded on both sides of the guides 102. The pockets 104, 104′ in these embodiment may be located directly opposite one another, or the pockets 104 on one side of a guide 102 may be staggered relative to the pockets 104′ on the opposite side of the guide 102.

In some embodiments, the electronic device 100 may have a single pocket 104 formed on one guide 102 and a single thermal interface 106 embedded in the pocket 104. In other embodiments, the electronic device 100 may have one pocket 104 formed on each guide 102 and a thermal interface 106 embedded in each pocket 104. In still other embodiments, the electronic device 100 may have multiple pockets 104 formed on each guide 102 and a thermal interface 106 embedded in each pocket 104. A given pocket 104 may be filled with only one thermal interface material in some embodiments, or it may be filled with more than one thermal interface material in some embodiments, arranged either side-by-side or stacked on top of one another. As well, non-uniform thermal interface materials and combinations of both uniform and non-uniform interface materials having the same or different properties may be used in a single electronic device 100 across one or multiple pockets 104 to achieve the desired results.

In some embodiments, the thermal interface 106 may be pre-applied to the pockets 104 of the devices 100, either on finished devices 100 or during assembly of the devices 100, then installed into the mounting assembly. Alternatively, similar pockets may be formed in a surface of a mounting assembly to which the devices 100 are installed, and similar thermal interfaces may be pre-applied to the pockets in the mounting assembly.

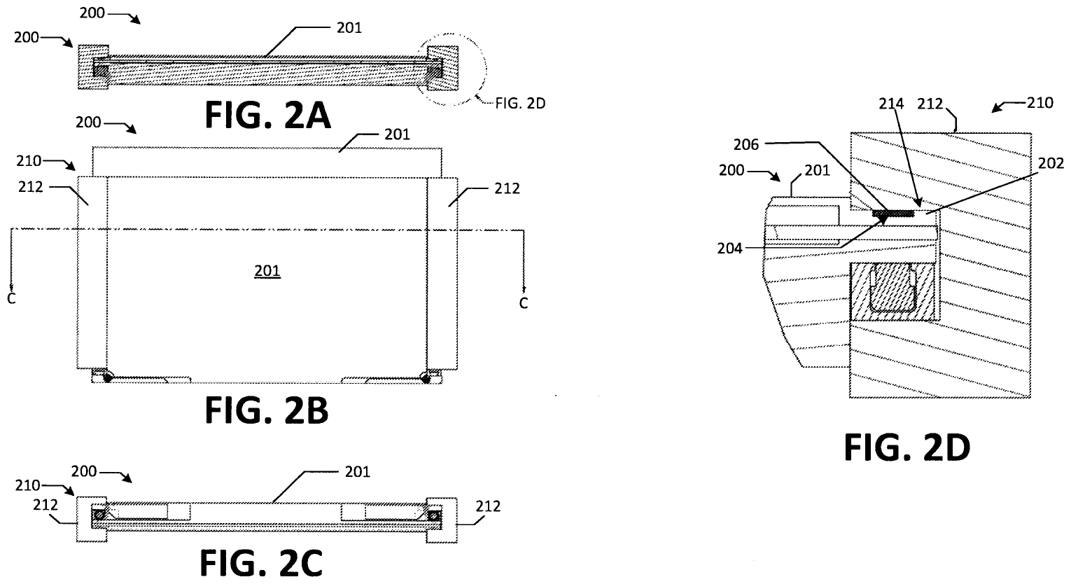

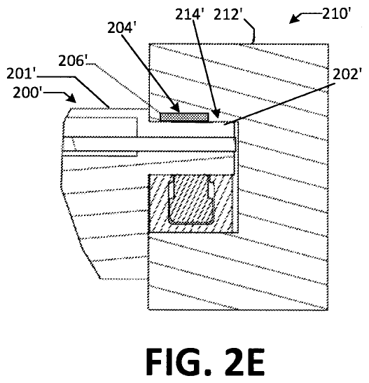

Turning now to FIGS. 2A, 2B, 2C, 2D, and 2E, cross-sectional front, top, side, and cross-sectional detail views of an electronic device 200 in a mounting assembly 210 are shown in accordance with embodiments of the present disclosure. As best seen in FIG. 2D, the electronic device 200 is similar to the electronic device 100 from FIGS. 1A, 1B, and 1C insofar as there is a main housing 201 composed of a thermally conductive material and having a generally rectangular guide 202 that resembles a ledge or step-down projecting from opposing sides of the main housing 201 in parallel to one another along the main housing 201. The guides 202 preferably, but not necessarily, extend along the full length of the main housing 201, each guide 201 having a plurality of generally rectangular, elongate thermal interface cavities or pockets 204, each having a predefined pocket depth, formed (e.g., machined) in a surface of the guides 202 roughly equal distance apart from one another. A generally rectangular, elongate thermal interface 206 is disposed within one or more, or each, of the thermal interface pockets 204, the thermal interface 206 having a predefined thickness that is slightly greater than the pocket depth of each pocket 204, such that a portion of the thermal interface 206 protrudes from the pocket 204.

The mounting assembly in this example resembles a card rack 210 having a mounting mechanism in the form of guide rails 212 composed of a thermally conductive material that correspond to the guides 202 of the electronic device 200. The guide rails 212 are designed to allow the electronic device 200 to be received in the card rack 210 by sliding the guides 202 of the device 200 into the guide rails 212. As best seen again in FIG. 2D, each guide rail 212 has a generally rectangular aperture or guide slot 214 formed therein extending along the length of each guide rail 212 for receiving a corresponding guide 202. When the device 200 is inserted into the card rack 210, the guide slots 214 of the guide rails 212 exert a clamping force on the guides 202 of the device 200 to secure the device 200 in the card rack 210. This clamping force causes the portion of the thermal interface 206 protruding beyond each pocket 204 to be compressed, thereby achieving flush physical (and hence thermal) contact on both sides of the thermal interface 206. When the compression of the thermal interface 206 reaches the guides 202, however, the top surface of the guides 202 counter the clamping force exerted by the guide slots 214 of the guide rails 212, thereby physically preventing compression of the thermal interfaces 206 further into the pockets 204.

In the present example, the pockets 204 machined on the device 200 are approximately 0.017 inches deep and the thermal interface 206 is approximately 0.020 inches thick. The thermal interface 206 would thus be approximately 25% compressed, depending on the mounting mechanism (guide rails 212) and device tolerances. The compression force applied to the top surface of the pockets 204 would then be prevented from acting further on the thermal interface 206. That compression force could thus be set independently of the thermal interface 206, based on structural and possibly other requirements not related to the material properties of thermal interface 206. The force withstood by the thermal interface 206 in the pocket 204, on the other hand, would be dictated by the specific interface material used, the nominal thickness of the thermal interface, and the percent compression.

FIG. 2E shows an alternative embodiment where, rather than the pocket 204 and the thermal interface 206 being disposed in the guides 202 of the electronic device 200, similar cavities or pockets 204′ may instead be formed in a surface of an alternative thermally conductive guide rail 212′ of an alternative card rack 210′. A similar thermal interface 206′ may then be disposed in the pockets 204′ of the guide rail 212′. Then, an electronic device 200′ having a housing 201′ with guides 202′ may be secured to the card rack 210′ by sliding the guides 202′ of the device 200′ into the guide slots 214′ of the guide rails 212′, like their counterparts in FIG. 2D. When the device 200′ is thus inserted into the card rack 210′, the guide slots 214′ of the guide rails 212′ exert a clamping force on the guides 202′ of the device 200′ to secure the device 200′ in the card rack 210′. As before, this clamping force causes the portion of the thermal interface 206′ protruding beyond each pocket 204′ to be compressed, thereby achieving flush physical (and hence thermal) contact on both sides of the thermal interface 206′. When the compression of the thermal interface 206′ reaches the pockets 204′, however, the top surface of the pockets 204′ counter the clamping force, thereby physically preventing compression of the thermal interfaces 206′ further into the pockets 204′.

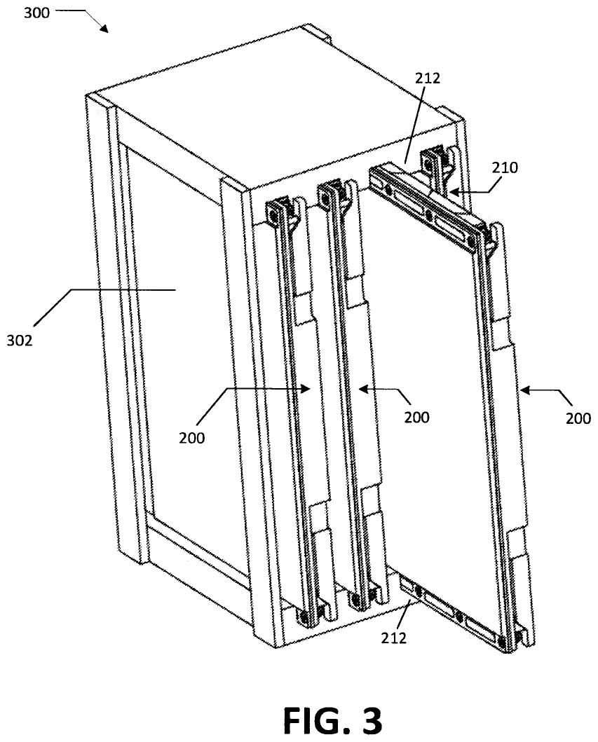

FIG. 3 shows a perspective view of an exemplary card cage 300 of a type that can be used to mount a plurality of electronic devices such as those shown in FIGS. 1 and 2 according to embodiments of the present disclosure. As can be seen, the card cage 300 has a housing 302 configured to enclose a plurality of card racks therein, each card rack designed to receive and securely mount an electronic device. In this example, the card cage 300 has several card racks that are similar in construction to the card rack 210 shown in FIG. 2. Thus, each of the card racks 210 in the card cage 300 has a pair of guide rails 212 designed to receive and securely mount an electronic device having an embedded thermal interface like the electronic device 200 shown in FIG. 2, such that the clamping force applied by the guide rails 212 to the embedded thermal interface is physically constrained or limited.

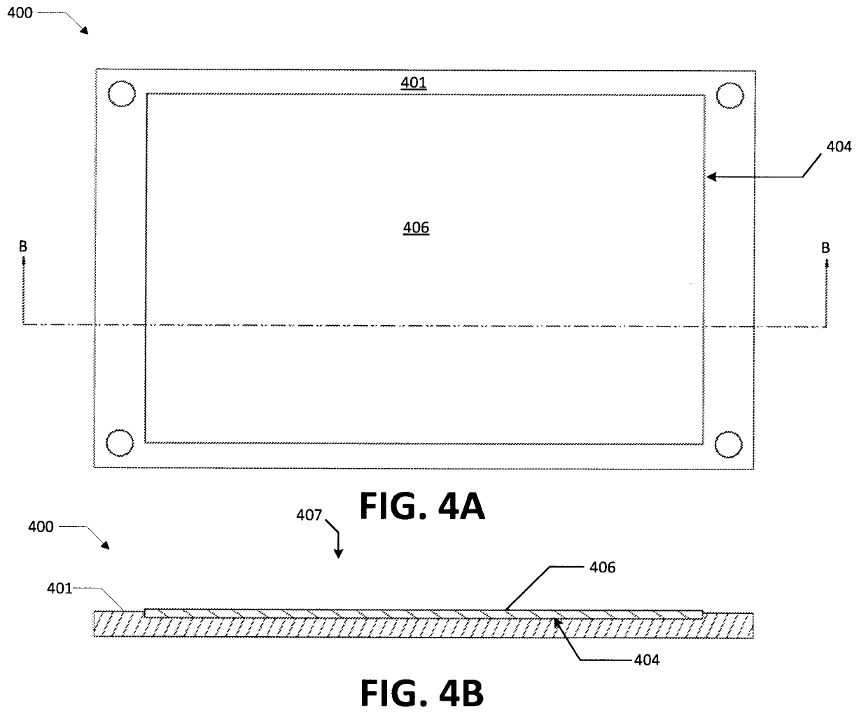

FIGS. 4A and 4B illustrate top and cross-sectional views of an electronic device 400 employing an alternative thermal interface system according to embodiments of the present disclosure. The electronic device 400 in this embodiment, like its counterpart in the previous figures, has a generally planar rectangular shaped housing 401 composed of a thermally conductive material. In this embodiment, however, a single thermal interface cavity or pocket 404 having a predefined pocket depth is formed (e.g., machined) in the center of the device 400 rather than several pockets along its outer opposing edges. A thermal interface 406 made of a resilient material or a material having an elastic property may then be embedded in the pocket 404 in a similar manner as described above. As seen in FIG. 4B, the thermal interface 406 has a predefined thickness that is slightly greater than the pocket depth of the pocket 404, and therefore a portion of thermal interface 406 protrudes from the pocket 404. As before, the surface of the device 400 from which the thermal interface material 406 protrudes is considered a mating face 407 of the device.

In some embodiments, the electronic device 400 is mounted to a mounting assembly by directly positioning the device on to the mounting assembly, then clamping the device 400 to the mounting assembly, rather than by sliding the device 400 into the mounting assembly. The device 400 and the mounting assembly may be attached to one another at the mating face 407 of the device 400 in these embodiments. The mounting assembly and the device 400 may be physically secured together using bolts, clamps, or other similar method in these embodiments. It is also possible, as alluded to above, to provide a pocket and thermal interface on the mounting assembly instead of the device 400.

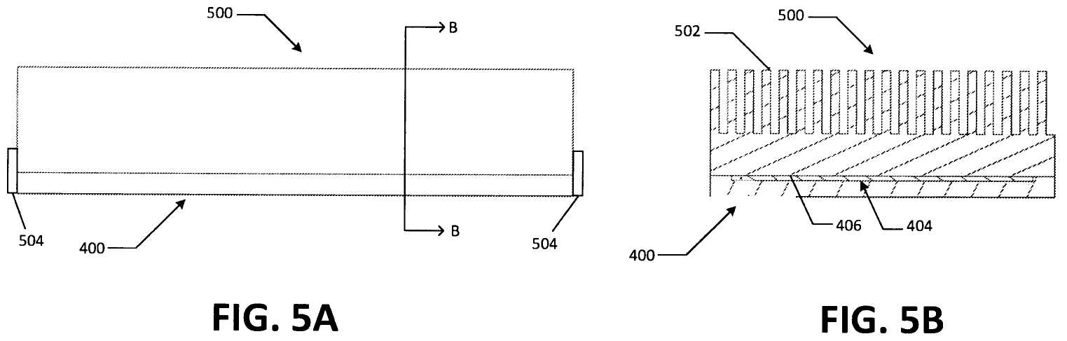

FIGS. 5A and 5B illustrate side and cross-sectional views of the electronic device 400 being mounted to an exemplary mounting assembly 500 according to embodiments of the present disclosure. The mounting assembly 500 in this example is a heatsink having a plurality of heat dissipating fins 502. In this embodiment, the electronic device 400 is attached directly to the heatsink 500, as opposed to being slid onto the heatsink 500. Latches 504 or similar attachment mechanisms may be used to apply a clamping force to secure the electronic device 400 to the heatsink 500. The clamping force applied by the latches 504 compresses the thermal interface 406 to establish flush physical (and hence thermal) contact between the thermal interface 406 and the heatsink 500.

As seen in FIG. 5B, the thermal interface pocket 404 protects the thermal interface 406 embedded therein and prevents the full clamping force of the latches 504 from being applied to the thermal interface 406. The thermal interface 406 is compressed only up to the point where the mating face of the device 400 (i.e., top surface of the pocket 404) meets the bottom surface of the heatsink 500. It will be appreciated that the heatsink 500 is only an example of a heat dissipating component that could be used with the device 400. Other heat dissipating components may include, but are not limited to, a cold plate, a thermal electric device, an evaporator, condenser, an electric heater, a fuel fired heater, a heat exchanger, an evaporative cooler, and the like.

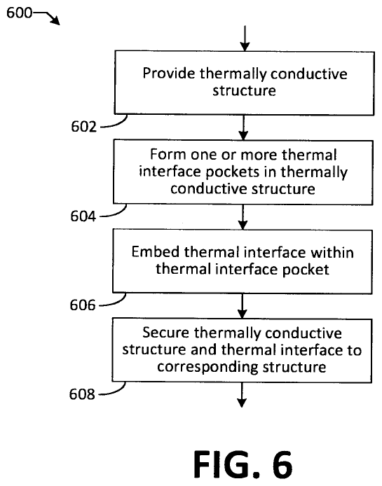

Thus far, several embodiments of the thermal interface system disclosed herein have been described. Following now in FIG. 6 is a method for implementing a thermal interface system according to embodiments of the present disclosure.

FIG. 6 illustrates a flowchart representing an exemplary method 600 that may be used to assemble a thermal interface system of the type described herein according to embodiments of the present disclosure. The method 600 generally begins at block 602, where a generally planar thermally conductive structure is provided. The thermally conductive material may be on or part of an electronic device of the type that is mounted in a cage, rack, chassis, or other mounting assembly, or it may be on or part of the mounting assembly, or both. For example, the thermally conductive structure may be on or part of a housing of the electronic device, or it may be on or part of a mounting guide projecting from the device. Alternatively, the thermally conductive structure may be on or part of a mounting mechanism of the mounting assembly to which the electronic device is mounted.

At block 604, one or more thermal interface cavities or pockets are formed in a surface of the thermally conductive structure, either on the electronic device or the mounting assembly, or both. The thermal interface pockets may be formed, for example, by machining or etching the pockets into the thermally conductive structure. Such a thermal interface pocket may have a generally rectangular shape in some embodiments, or other shapes may also be used, including a mix of different shapes. At block 606, a thermal interface having a shape corresponding to the shape of the thermal interface pockets is embedded within the thermal interface pockets. The thermal interface may be made of any suitable thermally conductive interface material that is resilient or has elastic properties that cause the thermal interface to try and return to its original shape and volume when compressed. Multiple such thermal interfaces may be combined in one thermal interface pocket in some embodiments. Importantly, the thermal interface has a predefined thickness that is greater than a predefined depth of the thermal interface pockets so that the thermal interface protrudes somewhat from the thermal interface pockets.

At block 608, the thermally conductive structure including the thermal interface within the thermal interface pocket is secured to either an electronic device, a mounting assembly, or some other corresponding structure. In some embodiments, a compressive force, such as a clamping force or bolting force, may be applied to secure the thermally conductive structure and the thermal interface therein to the corresponding structure. The clamping force may also be provided by sliding the thermally conductive structure into slot or other aperture, without the need for a separate clamping mechanism. As explained above, when the compressive force is applied, the portion of the thermal interface protruding beyond the thermal interface pocket is compressed. However, the pocket operates to counter the compressive force, thereby physically preventing the thermal interface from being further compressed. As a result, there is no need to rely on the mechanical properties of the thermal interface to withstand the compressive force, since the thermal interface cannot be compressed further into the pocket.

In some embodiments, as discussed, the above thermal interface arrangement may be used for heat conduction from an electronic device which uses structural geometry and structural material selection to provide clamping, without hardware or other clamping means. Examples include sliding the electronic device into a card rack that does not have additional clamping force applied after insertion, or a connector of any type which has a thermal interface that is comprised of an elastic thermal interface material constrained in a pocket.

In some embodiments, the thermal interface arrangement may be used for electronic devices which slide on mounting assembly surfaces and require heat transfer without being fixed in one or two axis parallel to the mounting assembly surface, or not fixed rotationally along a mounting assembly surface. For example, a device that is intended to slide or rotate which requires a heat transfer path while rotating could use a similar elastic thermal interface material constrained mechanically by pockets such that the pressure on the interface material is less than the pressure on the device and the supporting mating face.

The thermal interface material could be comprised of multiple materials. In one embodiment, the thermal interface material may be a thin layer of material which is chosen for low friction properties, and may not be significantly compressible, while the remainder of the thermal interface material may be selected for other properties, such as elastic properties that allow for the desired pressure and/or percent compression on the thermal interface when compressed. The various thermal interface materials may be attached to each other. Some attachment means may include: adhesive, welding, depositing, chemically, or other attachment means. In some embodiments, the various thermal interface materials may not be attached to each other using any attachment method, the various materials may not be otherwise constrained in the pocket. In such embodiments, the thermal interface material may be refreshed/reworked or replaced as needed.

Thus, the thermal interface arrangement of the present disclosure can be applied to any number of devices where the thermal interface is pre-embedded into the pockets, whether the device is sold as a part of other devices or structures to which the device is mounted, as well as full assemblies, and as separate components intended to be used to make full assemblies.

While a number of specific embodiments have been shown and described herein, it is to be understood that such embodiments are intended to be exemplary only. The scope of the present disclosure should therefore be determined with reference to the appended claims, including the full scope of equivalents to which such claims are entitled.

I/We claim:

1. An embedded thermal interface system, comprising:
a thermally conductive structure;
at least one thermal interface pocket formed in a surface of the thermally conductive structure, the at least one thermal interface pocket having a predefined pocket depth; and
a resilient thermal interface seated within the at least one thermal interface pocket, the resilient thermal interface having a predefined thermal interface thickness;
wherein the thermal interface thickness of the resilient thermal interface is greater than the pocket depth of the at least one thermal interface pocket, such that the resilient thermal interface protrudes from the at least one thermal interface pocket when the resilient thermal interface is seated within the at least one thermal interface pocket.

2. The system of claim 1, wherein when compressive force is applied to the resilient thermal interface, the at least one thermal interface pocket prevents the compressive force from being fully applied to the resilient thermal interface.

3. The system of claim 1, wherein the thermally conductive structure is on or part of a housing of an electronic device.

4. The system of claim 3, wherein the housing of the electronic device has mounting guides projecting therefrom and the at least one thermal interface pocket is formed in a surface of at least one of the mounting guides.

5. The system of claim 3, wherein the housing of the electronic device has a mating face thereon and the at least one thermal interface pocket is formed in a surface of the mating face.

6. The system of claim 1, wherein the thermally conductive structure is on or part of a mounting mechanism of a mounting assembly.

7. The system of claim 6, wherein the mounting mechanism of the mounting assembly is a guide rail and the thermal interface pocket is formed in a surface of the guide rail.

8. A method of assembling an embedded thermal interface system, the method comprising:
providing a thermally conductive structure;
forming at least one thermal interface pocket in a surface of the thermally conductive structure, the at least one thermal interface pocket having a predefined pocket depth; and
seating a resilient thermal interface within the at least one thermal interface pocket, the resilient thermal interface having a predefined thermal interface thickness;
wherein the thermal interface thickness of the resilient thermal interface is greater than the pocket depth of the at least one thermal interface pocket, such that the resilient thermal interface protrudes from the at least one thermal interface pocket when the resilient thermal interface is seated within the at least one thermal interface pocket.

9. The method of claim 8, further comprising applying compressive force to the resilient thermal interface, wherein the at least one thermal interface pocket prevents the compressive force from being fully applied to the resilient thermal interface.

10. The method of claim 8, wherein the thermally conductive structure is on or part of a housing of an electronic device.

11. The method of claim 10, wherein the housing of the electronic device has mounting guides projecting therefrom and the at least one thermal interface pocket is formed in a surface of at least one of the mounting guides.

12. The method of claim 10, wherein the housing of the electronic device has a mating face thereon and the at least one thermal interface pocket is formed in a surface of the mating face.

13. The method of claim 8, wherein the thermally conductive structure is on or part of a mounting mechanism of a mounting assembly.

14. The method of claim 13, wherein the mounting mechanism of the mounting assembly is a guide rail and the thermal interface pocket is formed in a surface of the guide rail.

15. An electronic assembly, comprising:
a card cage;
at least one electronic device mounted in the card cage; and
a thermal interface system disposed in the card cage, the thermal interface system comprising:
a thermally conductive structure;
at least one thermal interface pocket formed in a surface of the thermally conductive structure, the at least one thermal interface pocket having a predefined pocket depth; and
a resilient thermal interface seated within the at least one thermal interface pocket, the resilient thermal interface having a predefined thermal interface thickness;
wherein the thermal interface thickness of the resilient thermal interface is greater than the pocket depth of the at least one thermal interface pocket, such that the resilient thermal interface protrudes from the at least one thermal interface pocket when the resilient thermal interface is seated within the at least one thermal interface pocket.

16. The assembly of claim 15, wherein the thermally conductive structure is on or part of a housing of the electronic device.

17. The assembly of claim 16, wherein the housing of the electronic device has mounting guides projecting therefrom and the at least one thermal interface pocket is formed in a surface of at least one of the mounting guides.

18. The assembly of claim 16, wherein the housing of the electronic device has a mating face thereon and the at least one thermal interface pocket is formed in a mating surface the mating face.

19. The assembly of claim 15, wherein the thermally conductive structure is on or part of a mounting mechanism of the card cage.

20. The assembly of claim 20, wherein the mounting mechanism of the card cage is a guide rail and the thermal interface pocket is formed in a surface of the guide rail.
